(19) United States
(12) Patent Application Publication
(10) Pub. No.: US 2024/0274702 A1
(43) Pub. Date: Aug. 15, 2024

(54) HEMT TRANSISTOR

(71) Applicant: STMicroelectronics International N.V., Geneva (CH)

(72) Inventors: Aurore CONSTANT, Tours (FR); Ferdinando IUCOLANO, Gravina di Catania (IT); Cristina TRINGALI, Augusta (IT); Maria Eloisa CASTAGNA, Catania (IT)

(73) Assignee: STMicroelectronics International N.V., Geneva (CH)

(21) Appl. No.: 18/424,471

(22) Filed: Jan. 26, 2024

(30) Foreign Application Priority Data
Feb. 10, 2023 (FR) 2301258

(51) Int. Cl. H01L 29/778; H01L 29/20; H01L 29/205; H01L 29/66

(52) U.S. Cl. CPC H01L 29/778; H01L 29/2003; H01L 29/205; H01L 29/66462

(57) ABSTRACT

A HEMT transistor includes: a first semiconductor layer; a gate located on a first face of the first semiconductor layer; and a first passivating layer made of a first dielectric material which extends over the said first face of the first semiconductor layer, the sides of the gate, and at least a peripheral portion of a face of the gate opposite with respect to the first semiconductor layer, wherein a second passivating layer made of a second dielectric material extends between the said face of the gate and the first passivating layer, the sides of the gate being free of the said second passivating layer.

### CROSS-REFERENCE TO RELATED APPLICATION(S)

This application claims the priority benefit of French patent application number FR2301258, filed on Feb. 10, 2023, entitled “Transistor HEMT,” which is hereby incorporated by reference to the maximum extent allowable by law.

### BACKGROUND

### Technical Field

The present disclosure generally concerns the field of transistors and more particularly the field of high electron mobility transistors also called HEMT.

### Description of the Related Art

HEMT transistors rely on a heterojunction having a two-dimensional electron gas also called 2DEG forming at their surface.

There exists a need to improve HEMT transistors and their manufacturing methods.

### BRIEF SUMMARY

To achieve this, an embodiment provides A HEMT transistor comprising:
a first semiconductor layer;
a gate located on a first face of the first semiconductor layer; and
a first passivating layer made of a first dielectrical material which extends over the said first face of the first semiconductor layer, the sides of the gate, and at least a peripheral portion of a face of the gate opposite with respect to the first semiconductor layer,
wherein a second passivating layer made of a second dielectrical material extends between the said face of the gate and the first passivating layer, the sides of the gate being free of the said second passivating layer.

According to some embodiments, the first semiconductor layer is a gallium-nitride-based layer.

According to some embodiments, the first semiconductor layer is made of aluminum gallium nitride.

According to some embodiments, the first passivating layer is made of aluminum oxide.

According to some embodiments, the second passivating layer is made of nitride.

According to some embodiments, the second passivating layer is made of silicon nitride, of silicon carbonitride, or of aluminum nitride.

According to some embodiments, the second passivating layer is made of oxide, for example of aluminum oxide, or of silicon dioxide.

According to some embodiments, the transistor comprises a second semiconductor layer contacting a second face of the first semiconductor layer, on the side opposite to the first face.

According to some embodiments, the second semiconductor layer is made of gallium nitride.

According to some embodiments, the transistor comprises a source-contacting metallization and a drain-contacting metallization, located on either side of the gate, respectively.

Another embodiment provides a power conversion or matching circuit comprising at least one transistor according to the above embodiments.

Another embodiment provides a method for manufacturing a HEMT transistor comprising the following steps:
a) forming a first semiconductor layer;
forming a gate located on a first face of the first semiconductor layer; and
forming a first passivating layer made of a first dielectrical material which extends over the said first face of the first semiconductor layer, the sides of the gate and at least a peripheral portion of a face of the gate opposite with respect to the first semiconductor layer,
and wherein a second passivating layer made of a second dielectrical material extends between the said face of the gate and the first passivating layer, the sides of the gate being free of the said second passivating layer.

According to an embodiment, the method comprises the following successive steps:
depositing a layer made of the material of the gate on the first face of the first semiconductor layer;
depositing a layer made of the second dielectric material over the whole surface of the layer made of the material of the gate;
locally etching through a same etching mask, the layer made of the material of the gate and the layer made of the second dielectric material so that the gate and the second passivating layer are respectively formed.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial simplified cross-section view of an example of an HEMT transistor according to a first embodiment;

FIG. 2A, FIG. 2B, FIG. 2C, FIG. 2D, FIG. 2E, FIG. 2F and FIG. 2G are cross-section views illustrating steps of an example of a method of manufacturing the HEMT transistor illustrated in FIG. 1; and

FIG. 3 is a partial and simplified cross-section view of an example of an HEMT transistor according to a second embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the applications that the described HEMT transistors may have are not detailed, the embodiments being compatible with usual applications of HEMT transistors. The field of HEMT transistors, capable of withstanding relatively high voltages in the off state, for example, voltages in the order of from 100 to 650 volts, is more particularly considered herein. The described transistors can, for example, be used in various power conversion or matching circuits, such as in industrial equipment, display or lighting devices, telecommunications equipment, automotive device, etc.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made, unless specified otherwise, to the orientation of the figures.

Unless specified otherwise, the expressions “around,” “approximately,” “substantially” and “in the order of” signify within 10%, and preferably within 5%.

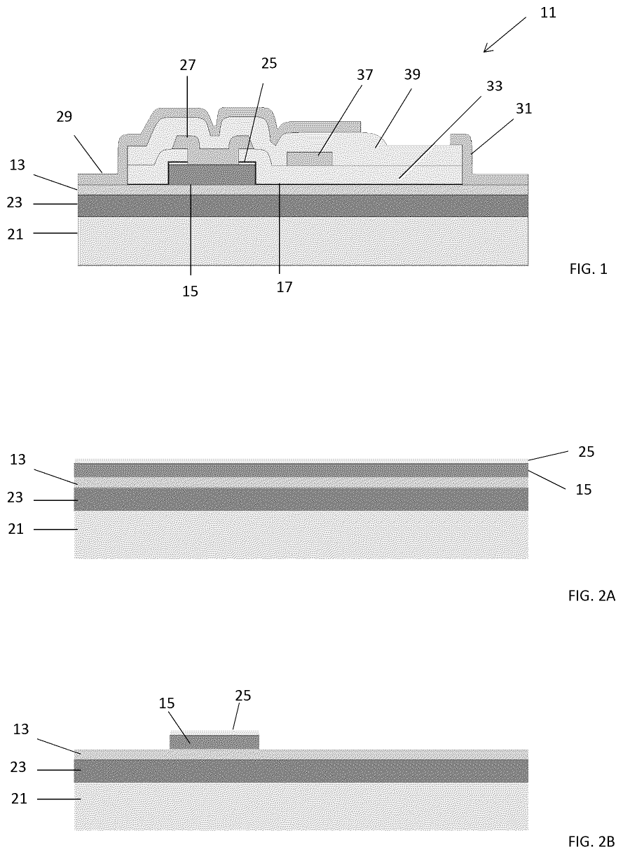

FIG. 1 is a partial simplified cross-section view of an example of an HEMT transistor 11 according to an embodiment.

HEMT transistor 11 comprises a first semiconductor layer 13 arranged on a second conductive layer 23. Semiconductor layer 23 is for example in contact, by its lower surface, with the upper surface of conductive layer 23. As an example, the stack comprising semiconductor layer 13 and semiconductor layer 23 rests on a substrate 21. Semiconductor layer 23 is for example in contact, by its lower surface, with the upper surface of substrate 21. The interface between semiconductor layer 13 and semiconductor layer 23 defines a heterojunction at the surface of which a two-dimensional electron gas 2DEG also called electron channel is formed.

Semiconductor layers 13 and 23 are for example made of semiconductor materials of III-V type, for example, based on gallium nitride (GaN). Semiconductor layer 13 is for example made of aluminum-gallium nitride (AlGaN). Semiconductor layer 23 is for example made of gallium nitride (GaN).

As an example, substrate 21 is made of a semiconductor material. Substrate 21 is for example made of silicon, or of silicon carbide. As a variant, substrate 21 is made of aluminum nitride. Substrate 21 for example comprises, on its upper surface side, a buffer layer, not detailed in the drawings, for example, made of gallium nitride. The buffer layer is for example in contact, by its upper surface, with the lower surface of semiconductor layer 23.

HEMT transistor 11 comprises a gate 15 on the upper surface of semiconductor layer 13. Gate 15 is for example in contact, by its lower surface, with the upper surface of semiconductor layer 13.

Gate 15 is for example made of a semiconductor material, for example of a semiconductor material of III-V type, for example, of gallium nitride, for example, P-type doped.

As an example, HEMT transistor 11 further comprises a source contact metallization 29 and a drain contact metallization 31. As an example, contact metallizations 29 and 31 are based on titanium, titanium nitride, and/or on an alloy of aluminum and of copper. Source and drain contact metallizations 29 and 31 for example each define an ohmic contact with semiconductor layer 13. Contact metallizations 29 and 31 are for example located on top of and in contact with semiconductor layer 13, on either side of gate 15.

HEMT transistor 11 further comprises a passivation layer 25, made of a dielectric material, extending on the upper surface of gate 15 but which does not extend on the sides of the gate. Passivation layer 25 is for example in contact, by its lower surface, with the upper surface of gate 15.

Passivation layer 25 for example has a thickness in the range from 1 nm to 20 nm, for example in the range from 1 nm to 10 nm, for example, in the order of 2 nm.

Passivation layer 25 is for example made of nitride, for example of silicon nitride (Si₃N₄), of silicon carbonitride (SiOₓN_{y}), or of aluminum nitride (AlN). Passivation layer 25 is for example made of oxide, for example, of alumina (Al₂O₃) or of silicon dioxide (SiO₂).

HEMT transistor 11 further comprises a passivation layer 17 covering the sides and at least a portion of the upper surface of passivation layer 25, the sides of gate 15, and extending over a portion of the upper surface of semiconductor layer 13 not covered with gate 15. As an example, passivation layer 17 is in contact, by its lower surface, with the upper surface of semiconductor layer 13. Passivation layer 17 is for example further in contact with the sides of gate 15. Passivation layer 17 is for example further in contact, by its lower surface, with the upper surface of semiconductor layer 13. In the embodiment of FIG. 1, passivation layer 17 extends laterally between the source and drain contact metallizations 29 and 31.

Passivation layer 17 for example has a thickness in the range from 2 nm to 20 nm, for example in the range from 2 nm to 10 nm, for example, in the order of 5 nm. Passivation layer 17 is for example made of a dielectric material, for example, of alumina (Al₂O₃), of silicon dioxide (SiO₂), of aluminum nitride (AlN), or of hafnium acid (HfO₂).

Gate 15 is for example topped with a gate contact metallization 27.

As an example, gate contact metallization 27 is in contact, by its lower surface, with the upper surface of gate 15. Gate contact metallization 27 then extends through layers 17 and 25, which only cover the upper surface of gate 15 on its periphery.

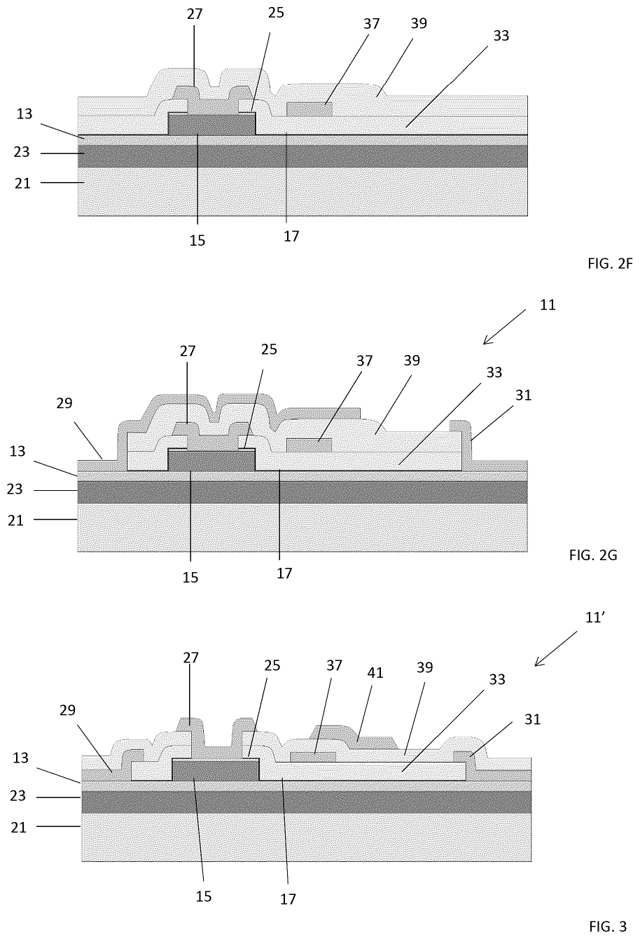

As a variant, gate contact metallization 27 is in contact, by its lower surface, with the upper surface of passivation layer 25 which extends over the entire surface of the upper surface of gate 15. Gate contact metallization 27 then extends through layer 17, which only covers passivation layer 25 on its periphery. This variant is illustrated for example by FIG. 3 described hereafter.

As an example, gate contact metallization 27 is based on titanium nitride and/or on titanium, and/or on tantalum, and/or an alloy of tungsten and tantalum, and/or an alloy of tungsten and titanium, and/or on an alloy of aluminum and copper.

HEMT transistor 11 for example comprises a plurality of levels of insulating layers inside and for example on top of which are formed metallizations.

As an example, HEMT transistor 11 comprises an insulating layer 33 on top of and in contact with the upper surface of passivation layer 17. As an example, insulating layer 33 covers the entire surface of passivation layer 17. Insulating layer 33 is for example opened in front of a central portion of gate 15 to be crossed by gate contact metallization 27. Insulating layer 33 is for example made of a dielectric material, for example, of an oxide, for example, of silicon dioxide (SiO₂).

As an example, HEMT transistor 11 comprises a metal region 37 extending over a portion of the surface of insulating layer 33. As an example, metal region 37 is based on titanium nitride and/or on titanium, and/or on tantalum, and/or an alloy of tungsten and tantalum, and/or an alloy of tungsten and titanium, and/or on an alloy of aluminum and copper. Metal region 37 is for example made of the same material as gate contact metallization 27.

HEMT transistor 11 may comprise a second insulating layer 39 covering the entire structure except for source and drain contact metallizations 29 and 31. Second insulating layer 39 is, for example, made of the same material as insulating layer 33.

As an example, source contact metallization 29 further extends on the upper surface of insulating layer 39 towards drain contact metallization 31, without reaching drain contact metallization 31.

In the transistor of FIG. 1, the 2DEG channel is for example normally off, that is, it is interrupted under gate 15, which prevents the flowing of a current between the source and the drain of the transistor. The transistor is said to be in the off state. The channel may be restored (that is, made conductive) by the biasing of gate 15. In this case, a current may establish between the source and the drain of the transistor. The described embodiments may also apply to normally-on transistors.

The presence of passivation layer 17 allows the protection of the upper surface of semiconductor layer 13 on which dangling bonds may be present and likely to generate leakage currents and/or a decrease in the breakdown voltage of the transistor. Passivation layer 17 fills these bonds to make the surface of semiconductor layer 13 electrically inactive.

Passivation layer 17 also enables to protect semiconductor layer 13 against oxidation and to improve its surface state to which the 2DEG channel is sensitive.

While passivation layer 17 plays an important role in the quality and lifetime of the transistor, its presence may cause the accumulation of electrons along the sides of gate 15, under passivation layer 17. This phenomenon is for example enhanced by the damaging of the sides of the gate cause by the etching of gate 15. The presence of passivation layer 25 on the upper surface of gate 15 allows the decrease of the lateral leakage current originating from the upper surface of gate 15 and conveyed by these electrons.

Gate 15, preferably formed by epitaxy, for example has a gallium polarity, that is, in its atomic arrangement, gate 15 ends at the level of its upper surface with gallium atoms, thus leaving nitrogen vacancies at the surface of this surface. An advantage in the forming of a second nitride passivation layer 25 at the surface of the upper surface of gate 15 is that it enables to fill the nitrogen vacancies, present at the surface of the upper surface of gate 15, likely to generate leakage currents.

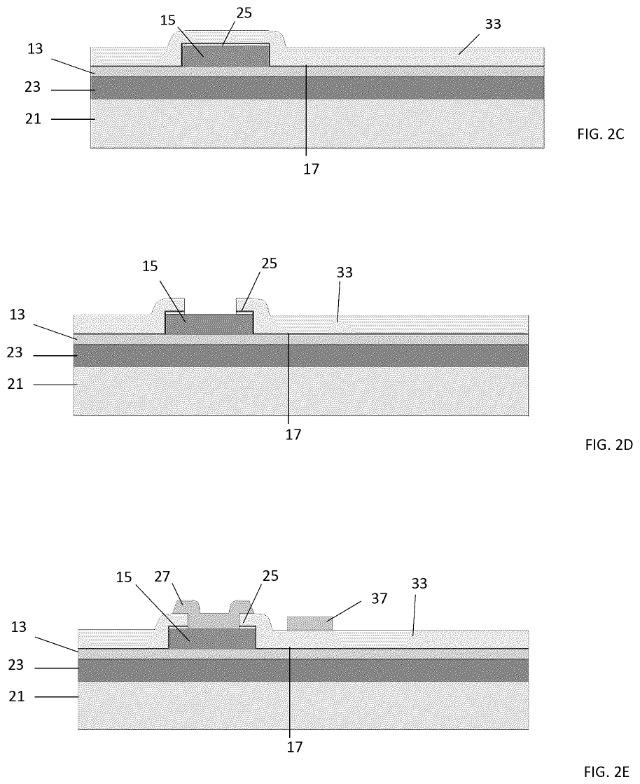

FIG. 2A, FIG. 2B, FIG. 2C, FIG. 2D, FIG. 2E, FIG. 2F and FIG. 2G are cross-section views illustrating successive steps of an example of a method of manufacturing the HEMT transistor illustrated in FIG. 1.

FIG. 2A illustrates an initial structure comprising, in the order, from the lower surface of the structure, substrate 21, second semiconductor layer 23, and first semiconductor layer 13. The initial structure further comprises a gate layer 15 topped with passivation layer 25. In the initial structure illustrated in FIG. 2A, layers 23, 13, 15, and 25 extend continuously and with a substantially uniform thickness over the entire upper surface of substrate 21.

As an example, gate 15 is formed on the upper surface of layer 13, by a vapor deposition method, for example, a metal organic chemical vapor deposition or MOCVD method. As an example, the deposition of gate 15 is performed under an at least partial vacuum.

As an example, passivation layer 25 is formed on the upper surface of gate 15 by MOCVD, for example under an at least partial vacuum. In this example, passivation layer 25 and gate 15 are formed in the same chamber with no rupture of vacuum between the two depositions. Such a deposition method is for example used for the forming of a nitride passivation layer 25, for example made of silicon nitride or of aluminum nitride.

As a variant, passivation layer 25 is formed, on the upper surface of gate 15, by an atomic layer deposition or ALD method. As an example, the method of deposition of passivation layer 25 is plasma-enhanced. Such a deposition method is for example used for the forming of a nitride passivation layer 25, for example made of silicon nitride, of aluminum nitride, or of silicon carbonitride.

FIG. 2B illustrates a structure obtained at the end of a step of local etching of gate layer 15 and of passivation layer 25 to only keep a portion of each layer forming the gate stack of the transistor of FIG. 1.

During this step, passivation layer 25 is etched for example by a plasma etching method, for example by a method of plasma etching based on chlorine, for example by a boron trichloride (BCl₃) plasma etching.

During this step, gate 15 is further etched for example by a plasma etching method, for example by a chlorine-based plasma etching method, for example, by a chlorine (Cl₂) and oxygen (O₂) plasma etching.

As an example, gate 15 and passivation layer 25 are etched through a same mask. At the end of this step, gate 15 and passivation layer 25 are thus aligned, that is, they have their sides aligned.

The steps of etching of gate 15 and of passivation layer 25 are for example carried out simultaneously, that is, they are formed within a same etch chamber. As a variant, the steps of etching of gate 15 and of passivation layer 25 are successively performed one after the other.

These etch steps are for example followed by a step of cleaning of the upper surface of the structure to for example remove residues originating from the etch mask(s) and the impurities resulting from the etching of passivation layer 25 and of gate 15. The cleaning of the structure for example comprises a step of stripping by oxygen and nitrogen (N₂) plasma. The cleaning of the structure may further comprise a step of removal of organic residues by means of a solvent.

FIG. 2C illustrates a structure obtained at the end of a step of forming of passivation layer 17 and of insulating layer 33 on the upper surface of the structure illustrated in FIG. 2B.

During this step, passivation layer 17 is first manufactured in continuous fashion, so that it covers the entire upper surface of the structure illustrated in FIG. 2B.

Passivation layer 17 is for example formed in contact with the upper surface of semiconductor layer 13, the sides of gate 15, and the sides and the upper surface of passivation layer 25.

Passivation layer 17 is for example formed by a thin layer deposition method, for example by ALD. As an example, the method of deposition of passivation layer 17 is plasma-enhanced.

Then, insulating layer 33 is, in this example, formed in continuous fashion, so that it covers the entire upper surface of passivation layer 17. Insulating layer 33 is for example formed in contact with passivation layer 17. Insulating layer 33 is for example formed by a plasma-enhanced chemical vapor deposition or PECVD. At the end of this step, insulating layer 33 has a thickness for example in the range from 150 nm to 400 nm, for example in the range from 200 nm to 350 nm, for example, in the order of 260 nm.

As an example, the steps of deposition of passivation layer 17 and of insulating layer 33 are preceded by one or a plurality of steps of preparation of the surface of the structure illustrated in FIG. 2B. The preparation of the surface of the structure illustrated in FIG. 2B may comprise a cleaning for example consisting of a chemical cleaning by means of acid, for example, hydrogen chloride (HCl) or hydrogen fluoride (HF). The preparation of the surface of the structure illustrated in FIG. 2B may further comprise a cleaning for example consisting of a surface oxidation. Passivation layer 17 will thus be formed in contact with an oxide film, itself formed in contact with the upper surface of layer 13.

FIG. 2D illustrates a structure obtained at the end of a step of opening of layers 17, 25, and 33 in front of gate 15 of the structure illustrated in FIG. 2C.

More particularly, during this step, passivation layers 17 and 25 and insulating layer 33 are removed in front of a central portion of the upper surface of gate 15.

As an example, this step first comprises the removal of layer 33 and then the removal of layers 17 and 25. As an example, the removal of layer 33 is performed by plasma etching, for example, based on fluorine, for example, based on carbon tetrafluoride (CF₄).

As an example, the removal of layers 17 and 25 is performed by plasma etching, for example, based on chlorine, for example, based on boron trichloride (BCl₃). In this example, layers 17 and 25 are etched to expose the upper surface of gate 15.

As a variant, during this step, passivation layer 25 is not removed in front of the central portion of the upper surface of gate 15, the etching of passivation layer 17 being interrupted when the upper surface of passivation layer 25 is exposed.

The above-mentioned etchings are for example followed by a step of cleaning of the upper surface of the structure, for example similarly to what has been described in relation with FIG. 2B.

FIG. 2E illustrates a structure obtained at the end of a step of forming of metallization 27 and of region 37 on the upper surface of the structure illustrated in FIG. 2D.

During this step, gate contact metallization 27 is for example formed in the opening formed in layers 17 and 33 in front of the central portion of gate 15. As an example, gate contact metallization 27 is formed on top of and in contact with the upper surface of gate 15. As a variant, gate contact metallization 27 is formed on top of and in contact with the upper surface of passivation layer 25.

As an example, during this step, region 37 is further formed on a portion of the surface of first insulating layer 33. Gate contact metallization 27 and region 37 are for example formed by deposition of one or a plurality of layers made of a metallic material followed by an etching step.

As an example, the step of forming of gate contact metallization 27 and of region 37 is preceded by a step of preparation of the surface of the structure illustrated in FIG. 2D, for example consisting of a chemical cleaning by means of acid, for example, hydrogen chloride (HCl).

FIG. 2F illustrates a structure obtained at the end of a step of forming of insulating layer 39 on the upper surface of the structure illustrated in FIG. 2E.

During this step, insulating layer 39 is for example formed over the entire wafer, so that it covers the entire upper surface of the structure illustrated in FIG. 2E, that is, the upper surface and the side of gate contact metallization 27 and of region 37 and a portion of layer 33. Insulating layer 39 is for example formed by a method identical to the method of forming layer 33 described in relation with FIG. 2C. At the end of this step, insulating layer 39 has a thickness for example in the range from 150 nm to 400 nm, for example in the range from 200 nm to 350 nm, for example, in the order of 260 nm.

FIG. 2G illustrates a structure obtained at the end of a step of forming openings localized in the stack of dielectrical or dielectric layers 39, 33 and 17 so as to expose the upper surface of semiconducting layer 13 in front of source and drain contact regions of the transistor, followed by a step of forming source 29 and drain 31 contact metallizations in said openings. The structure thus obtained is for example identical or similar to the structure illustrated in FIG. 1.

The openings intended to receive source and drain contact metallizations 29 and 31 are for example formed by a plasma etching method, for example, based on fluorine, for example, based on carbon tetrafluoride (CF₄). The above-mentioned etching is for example selective and does not etch gallium nitride semiconductor layer 13. The etching of layers 17, 33, and 39 thus stops when the upper surface of layer 13 is exposed. The step of forming of the openings intended to receive contact metallizations 29 and 31 is for example followed by a step of cleaning of the upper surface of the structure, for example, similarly to what has been described in relation with FIG. 2B. As an example, a step of preparation of the surface of the upper surface of layer 13 in the openings, to accommodate contact metallizations 29 and 31, may be provided. This step for example comprises a chemical cleaning by means of acid, for example hydrogen chloride (HCl).

In a second phase, source and drain contact metallizations 29 and 31 are for example formed in the previously-formed openings. Metallizations 29, 31, and region 41 are for example formed by deposition of one or a plurality of layers made of a metallic material over the entire upper surface of the structure, here the upper surface of layers 13 and 39, followed by an etching step to laterally delimit the source 29 and drain 31 contact metallizations.

FIG. 3 is a partial and simplified cross-section view of an example of an HEMT transistor 11′ according to a second embodiment.

The transistor 11′ illustrated in FIG. 3 is similar to the transistor 11 illustrated in FIG. 1 with the difference that, in the method of manufacturing transistor 11′, source 29 and drain 31 contact metallizations have been formed before the forming of gate contact metallization 27 while in the methods of manufacturing transistor 11, source and drain contact metallizations 29 and 31 have been formed after the forming of gate contact metallization 27.

More particularly, in this example, transistors 11′ is different from transistor 11 in that gate contact metallization 27 crosses layer 39 and in that layer 39 covers contact metallizations 29 and 31.

Various embodiments and variants have been described. Those skilled in the art will understand that certain features of these various embodiments and variants may be combined, and other variants will occur to those skilled in the art.

Further, although an example of embodiment where the transistor gate 15 is in contact with the upper surface of upper semiconductor layer 13 has been described hereabove, as a variant, gate 15 may be separated from semiconductor layer 13 by a gate insulator layer.

Finally, the embodiments are not limited to the examples of numerical values nor to the examples of materials mentioned in the present disclosure.

Finally, the practical implementation of the described embodiments and variations is within the abilities of those skilled in the art based on the functional indications given hereabove.

A HEMT transistor (11) may be summarized as including: a first semiconductor layer (13); a gate (15) located on a first face of the first semiconductor layer (13); and a first passivating layer (17) made of a first dielectrical material which extends over the said first face of the first semiconductor layer, the sides of the gate (15), and at least a peripheral portion of a face of the gate opposite with respect to the first semiconductor layer, wherein a second passivating layer (25) made of a second dielectrical material extends between the said face of the gate and the first passivating layer, the sides of the gate (15) being free of the said second passivating layer (25).

The first semiconductor layer (13) may be a gallium-nitride-based layer.

The first semiconductor layer (13) may be made of aluminum gallium nitride.

The first passivating layer (17) may be made of aluminum oxide.

The second passivating layer (25) may be made of nitride.

The second passivating layer (25) may be made of silicon nitride, of silicon carbonitride, or of aluminum nitride.

The second passivating layer (25) may be made of oxide, for example of aluminum oxide (Al2O3), or of silicon dioxide (SiO2).

The transistor may include a second semiconductor layer (23) contacting a second face of the first semiconductor layer (13), on the side opposite to the first face.

The second semiconductor layer (23) may be made of gallium nitride.

The transistor may include a source-contacting metallization (29) and a drain-contacting metallization (31), located on either side of the gate (15), respectively.

A power conversion or matching circuit may be summarized as including at least one transistor.

A method for manufacturing a HEMT transistor may be summarized as including the following steps: a) forming a first semiconductor layer (13); forming a gate (15) located on a first face of the first semiconductor layer (13); and forming a first passivating layer (17) made of a first dielectrical material which extends over the said first face of the first semiconductor layer, the sides of the gate (15) and at least a peripheral portion of a face of the gate opposite with respect to the first semiconductor layer, and a second passivating layer (25) made of a second dielectrical material extends between the said face of the gate and the first passivating layer, the sides of the gate (15) being free of the said second passivating layer (25).

The method may include the following successive steps: depositing a layer made of the material of the gate (15) on the first face of the first semiconductor layer (13); depositing a layer made of the second dielectric material over the whole surface of the layer made of the material of the gate (15); locally etching through a same etching mask, the layer made of the material of the gate (15) and the layer made of the second dielectric material so that the gate (15) and the second passivating layer (25) are respectively formed.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A HEMT transistor comprising:
a first semiconductor layer;
a gate on a first face of the first semiconductor layer; and
a first passivating layer of a first dielectric material which extends over the said first face of the first semiconductor layer, sides of the gate, and at least a peripheral portion of a face of the gate opposite with respect to the first semiconductor layer,
a second passivating layer of a second dielectric material extends between the said face of the gate and the first passivating layer, the sides of the gate being free of the said second passivating layer.

2. The transistor according to claim 1, wherein the first semiconductor layer is a gallium-nitride-based layer.

3. The transistor according to claim 2, wherein the first semiconductor layer is aluminum gallium nitride.

4. The transistor according to claim 1, wherein the first passivating layer is aluminum oxide.

5. The transistor according to claim 1, wherein the second passivating layer is nitride.

6. The transistor according to claim 5, wherein the second passivating layer is silicon nitride, silicon carbonitride, or aluminum nitride.

7. The transistor according to claim 1, wherein the second passivating layer is aluminum oxide or silicon dioxide.

8. The transistor according to claim 1, comprising a second semiconductor layer that contacts a second face of the first semiconductor layer, on a second face opposite to the first face.

9. The transistor according to claim 8, wherein the second semiconductor layer is gallium nitride.

10. The transistor according to claim 1, comprising a source-contacting metallization and a drain-contacting metallization, on either side of the gate, respectively.

11. A method for manufacturing a HEMT transistor, comprising:
forming a first semiconductor layer;
forming a gate on a first face of the first semiconductor layer; and
forming a first passivating layer of a first dielectric material which extends over the said first face of the first semiconductor layer, sides of the gate and at least a peripheral portion of a face of the gate opposite with respect to the first semiconductor layer,
forming a second passivating layer of a second dielectric material extends between the said face of the gate and the first passivating layer, the sides of the gate being free of the said second passivating layer.

12. The method of claim 11, comprising:
forming a layer of a material of the gate on the first face of the first semiconductor layer;
forming a layer of the second dielectric material over the whole surface of the layer made of the material of the gate;
locally etching through a same etching mask, the layer of the material of the gate and the layer of the second dielectric material so that the gate and the second passivating layer are respectively formed.

13. A device, comprising:
a semiconductor stack, the semiconductor stack having a first face;
a gate layer being on top of the semiconductor stack on the first face, the gate layer having a second face, the second face different from the first face of the semiconductor stack;
a first passivation layer on the second face of the gate layer; and
a second passivation layer covering the first passivation layer and the first face of the semiconductor stack.

14. The device of claim 13, wherein the second face of the gate layer includes an opening, the first passivation layer and the second passivation layer cover the second face except that of the opening.

15. The device of claim 13, wherein the semiconductor stack includes:
a substrate;
a conductive layer on top of the substrate; and
a semiconductor layer on top of the conductive layer, wherein the semiconductor stack is configured to form a two-dimensional electron gas between the conductive layer and the semiconductor layer.

16. The device of claim 15, wherein the semiconductor layer is made of aluminum-gallium nitride.

17. The device of claim 16, wherein the conductive layer is of gallium nitride.

18. The device of claim 15, wherein the first passivating layer is of aluminum oxide.

19. The device of claim 18, wherein the second passivating layer is of aluminum oxide or of silicon dioxide.

20. The device of claim 18, wherein the second passivating layer is of silicon nitride, of silicon carbonitride, or of aluminum nitride.
